(19) United States
(12) Patent Application Publication
(10) Pub. No.: US 2012/0194458 A1
(43) Pub. Date: Aug. 2, 2012

(54) THREE-DIMENSIONAL FILTER INTEGRATED TOUCH PANEL, STEREO-SCOPIC IMAGE DISPLAY APPARATUS HAVING THE TOUCH PANEL AND MANUFACTURING METHOD FOR THE DISPLAY APPARATUS

(75) Inventor: Gap Young Kim, Seoul (KR)

(73) Assignee: LG Innotek Co., Ltd., Seoul (KR)

(21) Appl. No.: 13/361,269

(22) Filed: Jan. 30, 2012

(30) Foreign Application Priority Data
Jan. 31, 2011 (KR) 10-2011-0009420

(51) Int. Cl. G06F 3/041; H05K 13/00

(52) U.S. Cl. 345/173; 29/592.1

(57) ABSTRACT

The present invention relates to the three-dimensional filter integrated touch panel, comprising the first transparent electrode formed as the first pattern on the upper surface of the first substrate and the three-dimensional filter formed with the light shielding unit and with the light transmission unit arranged alternatively at the lower surface of the first substrate.

### CROSS-REFERENCE TO RELATED APPLICATION

This application claims the benefit under 35 U.S.C. §119 of Korean Patent Application No. 10-2011-0009420, filed Jan. 31, 2011, which is hereby incorporated by reference in its entirety.

### BACKGROUND

1. Field of the Invention

The present invention relates to a manufacturing method for a touch panel including a three-dimensional filter.

2. Description of the Related Art

Generally, a stereoscopic image display refers to a unit for sensing distance and volume of the image to a viewer by providing left eye and right eye of the viewer with different images, and an auto-stereoscopic device has been known, through which a user can view the three-dimensional image without wearing any device such as a polarimeter.

An ordinary auto-stereoscopic device divides in a space the images for left eye and right eye formed at an image display unit into the directions of the left eye and the right eye of a user, respectively, by using an optical separating element (or three-dimensional filter) such as lenticular lens or parallax barrier. As the prior arts related with such an auto-stereographic device, U.S. Pat. No. 5,465,175 and U.S. Pat. No. 6,046,849, etc., are cited.

In the stereoscopic image display using a three-dimensional filter such as a parallax barrier, an image display unit such as an LCD module has an arbitrary pattern of a plurality of sub-pixels corresponding to images for left eye and right eye. Further, the stereoscopic image display includes a light shielding unit and a light transmission unit of a slit shape in which a parallax barrier is arranged along the direction of the column of sub-pixels array at full length in front surface of the image display unit.

FIG. 1 is a cross-sectional view of a stereoscopic image display including a three-dimensional filter and a touch panel according to prior art.

As shown in FIG. 1, the prior three-dimensional filter 500 in a state of a light shielding unit 520 and a light transmission unit 530 are formed on a glass 510, independently from a touch panel 600, is laminated to the touch panel 600 and an UV resin 700 through a precise process. After that, a LED module 800 is laminated to the UV resin 700 under the three-dimensional filter 500 through an ultrafine process. However, the 2 times laminating processes have limitations to improving the align accuracy among the touch panel 600, the three-dimensional filter 500 and the LCD module 800 to display a stereoscopic image.

### BRIEF SUMMARY

The embodiments of the present invention provide a three-dimensional filter integrated touch panel, the stereoscopic image display provided with the three-dimensional filter integrated touch panel, capable of eliminating the process of laminating the three-dimensional filter and the touch panel together by forming the three-dimensional filter on one surface of the touch panel including the transparent electrode, and a manufacturing method thereof.

In addition, an embodiment of the present invention provides the three-dimensional filter integrated touch panel, the stereoscopic image display provided with the three-dimensional filter integrated touch panel, capable of reducing align error by performing only the process of laminating the touch panel and image display unit such as a LCD module together through the integration of the three-dimensional filter to the touch panel, and a manufacturing method thereof.

A three-dimensional filter integrated touch panel according to the present invention comprises a first transparent electrode formed as a first pattern on an upper surface of the first substrate, and a three-dimensional filter in which a light shielding unit and a light transmission unit are arranged alternatively on a lower surface of the first substrate.

The first substrate is made of any one among PET (polyethylene terephtalete), PC (polycarbonate), PES (polyether sulfone), PI (polyimide) and PMMA (PolyMethly MethaAcrylate).

The first transparent electrode is made of anyone selected among Indium Tin Oxide (ITO), Indium Zinc Oxide (IZO), Zinc Oxide (ZnO), carbon nano tube (CNT), Ag nano wire, conductive polymer and Graphene.

The light shielding unit is formed by depositing any one metal or an alloy of more than one metal among Gold (Au), Silver (Ag), Molybdenum (Mo), Copper (Cu) and Aluminum (Al).

The three-dimensional filter integrated touch panel further comprises a secondary substrate formed on the upper part of the first substrate, and a secondary transparent electrode formed as a secondary pattern on the upper surface of the secondary substrate.

A stereoscopic image display apparatus having a three-dimensional filter integrated touch panel according to an embodiment of the present invention comprises a touch panel comprising the first substrate and the three-dimensional filter in which light shielding unit and the light penetration unit are arranged alternatively on the lower part of the first substrate, an image display unit comprising a plurality of the first pixels corresponding the image for left eye and a plurality of the secondary pixels corresponding the image for right eye, and a first adhesive for laminating the touch panel and the image display unit together.

The image display unit is made of anyone among cathode ray tube, liquid crystal display element, plasma display panel, field emission display and organic field light emitting device.

The stereoscopic image display apparatus having the three-dimensional filter integrated touch panel further comprises a window layer formed on the upper part of the first transparent electrode which is formed as the first pattern on the upper surface of the first substrate, and a secondary adhesive for laminating the first transparent electrode and the window layer together.

The first and second adhesives use OCA (Optically Clear Adhesive) film or UV hardening adhesive.

A manufacturing method of the stereoscopic image display provided with the three-dimensional filter integrated touch panel according to an embodiment of the present invention comprises forming the light transmission unit and light shielding unit of the three-dimensional filter arranged alternatively on the lower surface of the first substrate included in the touch panel, adhering the window layer on the upper part of the first transparent electrode formed on the upper surface of the first substrate by using the second adhesive, and adhering the image display unit to the lower part of the three-dimensional filter by using the first adhesive.

The adhering by using the first and second adhesives comprises adhering any one or more among SVR, OCA and UV by using the first and second adhesives.

The forming the three-dimensional filter comprises depositing any one metal among Gold (Au), Silver (Ag), Molybdenum (Mo), Copper (Cu) and Aluminum (Al) on the lower surface of the first substrate, and pattering the metal into the light transmission unit and the light shielding unit.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a sectional view of a stereoscopic image display including the three-dimensional filter and the touch panel according to a prior art;

FIG. 2 is a cross-sectional view of the three-dimensional filter integrated touch panel according to an embodiment of the present invention;

FIG. 3 is a cross-sectional view of the stereoscopic image display provided with the three-dimensional filter integrated touch panel according to an embodiment of the present invention; and

FIG. 4 is a flowchart showing the manufacturing method of the stereoscopic image display provided with the three-dimensional filter integrated touch panel according to an embodiment of the present invention.

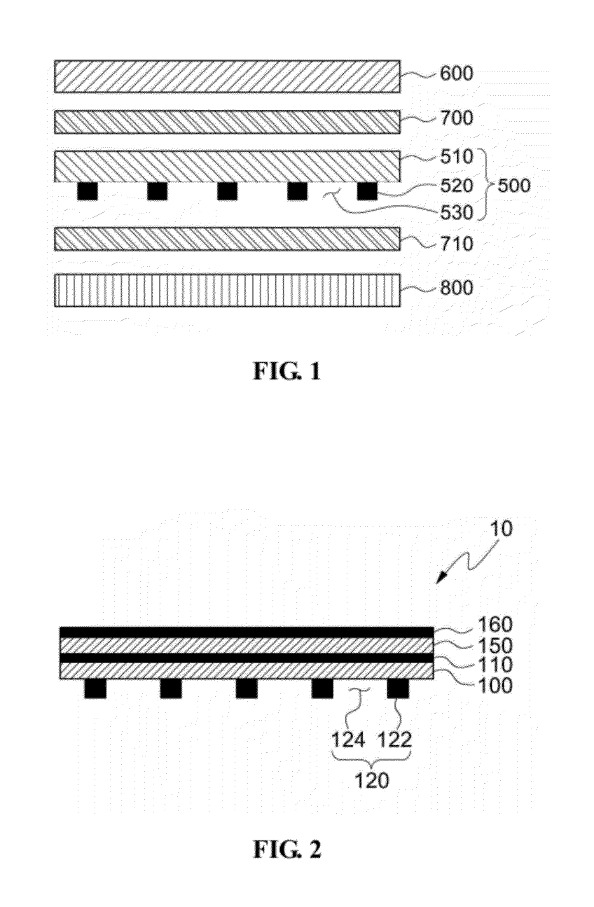

### DETAILED DESCRIPTION

Exemplary embodiments of the present invention will be described below in detail with reference to the accompanying drawings. Wherever possible, the same reference numerals will be used to refer to the same elements throughout the specification, and a duplicated description thereof will be omitted.

FIG. 2 is a sectional view of the three-dimensional filter integrated touch panel according to an embodiment of the present invention.

As shown in FIG. 2, the three-dimensional filter integrated touch panel 10 (hereinafter, referred to as “touch panel”) includes a three-dimensional filter 120 wherein light shielding unit 122 and the light transmission unit 124 are arranged alternatively, a first substrate 100 and a first transmission electrode 110.

As an embodiment, the touch panel 10 may be configured as 2 layers and further includes a secondary substrate 150 and a secondary transmission electrode 160 above the first substrate 100. Hereinafter the touch panel 10 referred to as “2 layers touch panel” including the first substrate 100 and the secondary substrate 150.

However, depending on the embodiment, the touch panel 10 may be configured as “1 layer touch panel” not including the secondary substrate 150 and the secondary transmission electrode 160. Otherwise, the touch panel 10 may further include a secondary transmission electrode formed as a secondary pattern between the low surface of the first substrate 100 and the three-dimensional filter 120, and thus the three-dimensional filter 120 may be formed the lower surface of the secondary transmission electrode.

As an embodiment, the first substrate 100 or the secondary substrate 150 may be made of anyone among polyethylene resin (polyethylene terephtalete, PET), PC (polycarbonate), PES (polyether sulfone), PI (polyimide) and PMMA (PolyMethly MethaAcrylate).

The first transmission electrode or the secondary transmission electrode may be made of anyone selected among ITO (Indium Tin Oxide), IZO (Indium Zinc Oxide), ZnO (Zinc Oxide), CNT (carbon nano tube), Ag nano wire, conductive polymer and Graphene.

The first pattern or the secondary pattern may be shaped as one among circle, semicircle, rectangular, polygon or lenticular form, and the formed shapes are connected vertically and repeatedly. However, the secondary pattern may be shaped as the same as the first pattern, or may be formed in an orthogonal direction to the first pattern.

The three-dimensional filter 120 may be formed as a parallax barrier by directly configuring light shielding unit 122 and the light transmission unit 124 on the lower surface (or backface) of the first substrate 100 making the touch panel 10, without using an additional substrate.

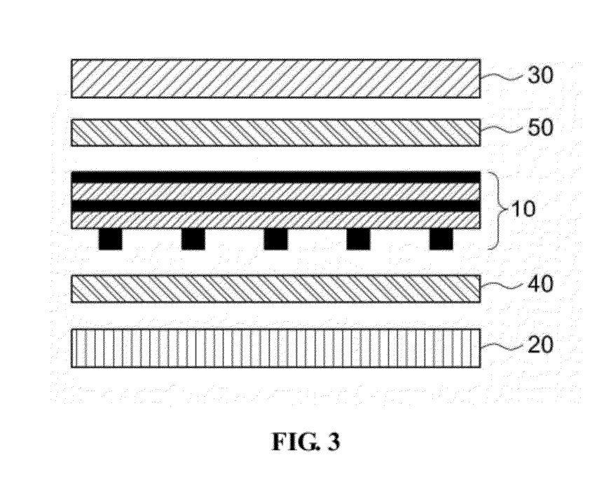

Accordingly, according to an embodiment of the present invention, the process of laminating the touch panel and the three-dimensional filter may be eliminated by configuring the three-dimensional filter on the first substrate forming the touch panel. For reference, according to a prior art, the touch panel and the three-dimensional filter are manufactured and then they have to be laminated together. However, in an embodiment of the present invention, the process of laminating the touch panel and the three-dimensional filter may be eliminated so that manufacturing process may be simplified. FIG. 3 is a cross-sectional view of the stereoscopic image display provided with the three-dimensional filter integrated touch panel according to an embodiment of the present invention.

As shown in FIG. 3, the stereoscopic image display provided with the three-dimensional filter integrated touch panel (hereinafter, referred to as “stereoscopic image display”) may include the touch panel 10, an image display unit 20 and a first adhesive 40.

The touch panel 10 may be formed as “1 layer touch panel”. In this case, the touch panel 10 may include the first substrate, the first transparent electrode formed as the first pattern on the upper surface of the first substrate, and the three-dimensional filter wherein light shielding unit and the light transmission unit are arranged alternatively on the lower surface of the first substrate.

As an embodiment, the touch panel 10 may further include a secondary transmission electrode formed as a secondary pattern between the low surface of the first substrate and the three-dimensional filter, and thus the three-dimensional filter may be formed the lower surface of the secondary transmission electrode.

As another embodiment, the touch panel 10 may be formed as a 2 layers touch panel. In this case, the touch panel 10 may include the secondary substrate, the first substrate forming the secondary transparent electrode 160 on the upper surface of the secondary substrate and including the first transparent electrode on the lower surface of the secondary substrate, and the three-dimensional filter in which the light shielding unit and the light transmission unit are arranged alternatively on the lower surface of the first substrate.

The first transparent electrode and the secondary transparent electrode may be formed as the first pattern and the secondary pattern to recognize positions of planar coordinate in vertical and horizontal directions, corresponding to a touch position.

The descriptions of the substrate, the transparent electrode and the pattern will be omitted in FIG. 3, as it is described in detail in FIG. 2.

Referring to FIG. 2, the three-dimensional filter 120 has the light shielding unit 122 and the light transmission unit 124 formed as a stripe shape and arranged alternatively on the lower surface of the first substrate 100 and serves as a parallax barrier enabling selectively a light shielding and a light transmission for implementing the three-dimensional stereoscopy. In other words, the three-dimensional filter 120 is accurately aligned with respect to the first and the secondary pixels configuring the image display unit 20 located in the lower part thereof to selectively shield transmit the images for left eye and right eye corresponding to the pixels. The light shielding unit 122 may be configured by depositing any one metal or an alloy of more than one metal among Gold (Au), Silver (Ag), Molybdenum (Mo), Copper (Cu) or Aluminum (Al).

As an embodiment, the stereoscopic image display may include a window layer 30 on the upper part of the first substrate.

The stereoscopic image display may be aligned accurately and easily by laminating the image display unit 20 to the lower part of the touch panel 10, and under this configuration the three-dimensional image display is possible available through the control of light shielding and light transmission the images for left eye and for right eye emitting from the image display unit 20.

The image display unit 20 may include a plurality of the first pixels corresponding to the image for left eye and a plurality of the secondary pixels corresponding to the image for right eye on the lower part of the three-dimensional filter 120. For this configuration, the image display unit may be formed with a color filter (not shown) in which sub pixels in red (R), green (G) and blue (B) are patterned. Such an image display unit 20 may be made of anyone among cathode ray tube (CRT), liquid crystal display (LCD) element, plasma display panel (PDP), field emission display (FED) and organic field light emitting device (OLED).

The first adhesive 40 is used to attach the three-dimensional filter 120 and image display unit 20 together, while the secondary adhesive 50 is used to attach the first transparent electrode 110 and the window layer 30 together.

For the first adhesive 40 and the secondary adhesive 50, OCA (Optically Clear Adhesive) film or UV hardening adhesive may be used. For OCA Re-workable OCA film may be used as the OCA film. In using UV hardening adhesive, SVR (Super View Resin) method is available.

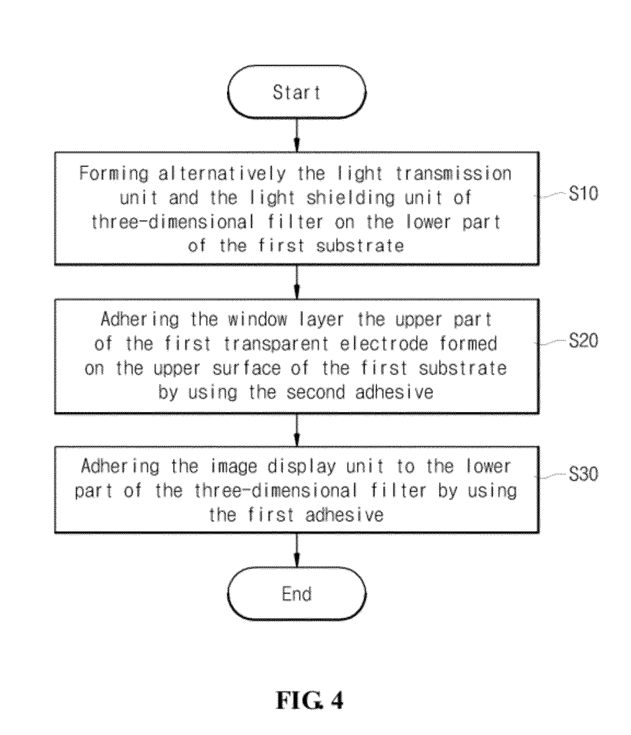

FIG. 4 is a flowchart showing the manufacturing method of the stereoscopic image display provided with the three-dimensional filter integrated touch panel according to an embodiment of the present invention.

Referring to FIG. 4, the manufacturing method of the stereoscopic image display provided with the three-dimensional filter integrated touch panel (hereinafter, referred to as “manufacturing”) including forming alternatively the light transmission unit 124 and light shielding unit 122 of the three-dimensional filter 120 on the lower surface of the first substrate 100 included in the touch panel 10 (S10). In this case, the touch panel 10 refers to as a 1 layer capacitance touch panel. The manufacturing method may be performed by forming the first transparent electrode 110 on the upper surface of the first substrate 100 as the first pattern before configuring the three-dimensional filter 120.

If the touch panel 10 is the 2 layers capacitance touch panel, a procedure of arranging the secondary substrate 150 on an upper part of the first substrate 100 and forming the secondary transparent electrode 160 having the secondary pattern on the secondary substrate 150, before the configuration (S10) of the three-dimensional filter 120, may be further included. The window layer 30 is laminated on the upper part of the first transparent electrode 110 using the secondary adhesive 50 (S20). In this case, if the touch panel is the 2 layers capacitance touch panel, the window layer 30 will be laminated on the upper part of the secondary transparent electrode 160.

The image display unit 20 may be laminated on the lower part of the three-dimensional filter 120 using the first adhesive 40 (S30).

The image display unit 20 may include a plurality of the first pixels corresponding to the image for left eye and a plurality of the secondary pixels corresponding to the image for right eye.

Here, the three-dimensional filter 120 may be formed (S10) by depositing any one or more metals among Gold (Au), Silver (Ag), Molybdenum (Mo), Copper (Cu) and Aluminum (Al) to the lower surface of the first substrate 100, and pattering the metal into the light transmission unit 124 and light shielding unit 122. Particularly, metal patterning process can be executed through a Photolithography process including light exposition, development and etching to deposited metal.

According to an embodiment of the present invention, the process for laminating the three-dimensional filter and the touch panel is eliminated by forming the three-dimensional filter on one side of on one surface of the substrate of the touch panel including the transparent electrode.

According to an embodiment of the present invention, align error is reduced by performing the process of laminating the touch panel with the image display unit such as LCD module through the integration of the three-dimensional filter and the touch panel.

While the invention has been shown and described with reference to exemplary embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

What is claimed is:

1. A three-dimensional filter integrated touch panel comprising:
a first transparent electrode formed as a first pattern on an upper surface of the first substrate; and
the three-dimensional filter in which a light shielding unit and a light transmission unit are arranged alternatively on a lower surface of the first substrate.

2. The three-dimensional filter integrated touch panel of claim 1, wherein the first substrate is made of anyone among PET (polyethylene terephtalete), PC (polycarbonate), PES (polyether sulfone), PI (polyimide) and PMMA (PolyMethly MethaAcrylate).

3. The three-dimensional filter integrated touch panel of claim 1, wherein the first transparent electrode is made of anyone selected among Indium Tin Oxide (ITO), Indium Zinc Oxide (IZO), Zinc Oxide (ZnO), carbon nano tube (CNT), Ag nano wire, conductive polymer and Graphene.

4. The three-dimensional filter integrated touch panel of claim 1, wherein the light shielding unit is formed by depositing any one metal or an alloy of more than one metal among Gold (Au), Silver (Ag), Molybdenum (Mo), Copper (Cu) and Aluminum (Al).

5. The three-dimensional filter integrated touch panel of claim 1, further comprises:
a secondary substrate formed on the upper part of the first substrate; and
a secondary transparent electrode formed as a secondary pattern on the upper surface of the secondary substrate.

6. A stereoscopic image display apparatus having a three-dimensional filter integrated touch panel, comprising:
the touch panel comprising the first substrate and the three-dimensional filter in which light shielding unit and the light penetration unit are arranged alternatively on the lower part of the first substrate;
an image display unit comprising a plurality of the first pixels corresponding the image for left eye and a plurality of the secondary pixels corresponding the image for right eye; and
a first adhesive for laminating the touch panel and the image display unit together.

7. The stereoscopic image display apparatus having a three-dimensional filter integrated touch panel of claim 6, wherein the image display unit is made of anyone among cathode ray tube, liquid crystal display element, plasma display panel, field emission display and organic field light emitting device.

8. The stereoscopic image display apparatus having a three-dimensional filter integrated touch panel of claim 6, further comprises:
a window layer formed on the upper part of the first transparent electrode which is formed as the first pattern on the upper surface of the first substrate; and
a secondary adhesive for laminating the first transparent electrode and the window layer together.

9. The stereoscopic image display apparatus having a three-dimensional filter integrated touch panel of claim 6, wherein the first and second adhesives uses OCA (Optically Clear Adhesive) film or UV hardening adhesive.

10. A manufacturing method of a stereoscopic image display apparatus having a three-dimensional filter integrated touch panel, comprising:
forming a light transmission unit and a light shielding unit of the three-dimensional filter arranged alternatively on the lower surface of the first substrate included in the touch panel;
adhering the window layer on the upper part of the first transparent electrode formed on the upper surface of the first substrate by using the second adhesive; and
adhering the image display unit on the lower part of the three-dimensional filter by using the first adhesive.

11. The manufacturing method of the stereoscopic image display provided with a three-dimensional filter integrated touch panel of claim 10, wherein the adhering by using the first and second adhesives comprises adhering any one or more among SVR, OCA and UV by using the first and second adhesives.

12. The manufacturing method of the stereoscopic image display provided with a three-dimensional filter integrated touch panel of claim 10, wherein the forming the three-dimensional filter comprises depositing any one metal among Gold (Au), Silver (Ag), Molybdenum (Mo), Copper (Cu) and Aluminum (Al) on the lower surface of the first substrate, and pattering the metal into the light transmission unit and the light shielding unit.

13. The stereoscopic image display apparatus having a three-dimensional filter integrated touch panel of claim 8, wherein the first and second adhesives uses OCA (Optically Clear Adhesive) film or UV hardening adhesive.
